(19) United States
(12) Patent Application Publication
(10) Pub. No.: US 2009/0065826 A1
(43) Pub. Date: Mar. 12, 2009

(54) Image Sensor and Method for Manufacturing the Same

(76) Inventor: JOON HWANG, Cheongju-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/204,879

(22) Filed: Sep. 5, 2008

(30) Foreign Application Priority Data
Sep. 7, 2007 (KR) 10-2007-0091082

(51) Int. Cl. H01L 33/00; H01L 21/00

(52) U.S. Cl. 257/292; 438/69; 257/E33.001; 257/E21.001

(57) ABSTRACT

Provided is an image sensor. The image sensor can include a first substrate, an image sensing device and a light shielding layer. The first substrate includes a readout circuitry and an interconnection. The image sensing device is formed on the interconnection. The light shielding layer is formed in portions of the image sensing device on a boundary between pixels.

### CROSS-REFERENCE TO RELATED APPLICATION

The present application claims the benefit under 35 U.S.C. §119 of Korean Patent Application 10-2007-0091082, filed Sep. 7, 2007, which is hereby incorporated by reference in its entirety.

### BACKGROUND

An image sensor is a semiconductor device for converting an optical image into an electrical signal. The image sensor is roughly classified as a charge coupled device (CCD) image sensor or a complementary metal oxide semiconductor (CMOS) image sensor (CIS).

In a related art CIS, a photodiode is formed in a substrate having readout circuitry using ion implantation. As the size of a photodiode reduces more and more for the purpose of increasing the number of pixels without an increase in a chip size, the area of a light receiving portion reduces, resulting in reduced image quality.

Also, since a stack height does not reduce as much as the reduction in the area of the light receiving portion, the number of photons incident to the light receiving portion also reduces due to diffraction of light, called airy disk.

As an alternative to overcome this limitation, an attempt of forming a photodiode using amorphous silicon (Si), or forming a readout circuitry on a Si substrate and forming a photodiode on the readout circuitry using a method such as wafer-to-wafer bonding has been made (referred to as a “three-dimensional (3D) image sensor). The photodiode is connected with the readout circuitry through an interconnection.

Meanwhile, according to a related art, there is a crosstalk problem between pixels.

Also, according to a related art, since the both the source and the drain at the sides of the transfer transistor are heavily doped with N-type impurities, a charge sharing phenomenon occurs. When the charge sharing phenomenon occurs, the sensitivity of an output image is reduced and an image error may be generated.

Also, according to the related art, because a photo charge does not readily move between the photodiode and the readout circuitry, a dark current is generated or saturation and sensitivity reduce.

### BRIEF SUMMARY

Embodiments of the present invention provide an image sensor that can inhibit a crosstalk problem between pixels while increasing a fill factor, and a manufacturing method thereof.

Embodiments also provide an image sensor that can reduce the occurrence of charge sharing while increasing a fill factor, and a manufacturing method thereof.

Embodiments also provide an image sensor that can minimize a dark current source and inhibit a reduction in saturation and sensitivity by providing a swift movement path for a photo charge between a photodiode and a readout circuitry, and a manufacturing method thereof.

In one embodiment, an image sensor can comprise: a first substrate including a readout circuitry and an interconnection; an image sensing device on the interconnection; and a light shielding layer on a boundary between pixels.

In another embodiment, a method for manufacturing an image sensor can comprise: forming a readout circuitry and an interconnection on a first substrate; forming an image sensing device in a second substrate; forming a trench in the image sensing device; forming a second conduction type ion implantation layer on the surface of the trench; forming a light shielding layer on the second conduction type ion implantation layer; bonding the first substrate and the second substrate, wherein the interconnection corresponds with the image sensing device; and selectively removing a portion of the second substrate such that the image sensing device remains on the first substrate.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to an embodiment.

FIGS. 2 to 9 are cross-sectional views of a method for manufacturing an image sensor according to an embodiment.

FIG. 10 is a cross-sectional view of an image sensor according to another embodiment.

FIG. 11 is a cross-sectional view of an image sensor according to yet another embodiment.

### DETAILED DESCRIPTION

Hereinafter, embodiments of an image sensor and a manufacturing method thereof are described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

It should be noted that the present disclosure is not limited to a complementary metal oxide semiconductor (CMOS) image sensor, but can be readily applied to any image sensor requiring a photodiode.

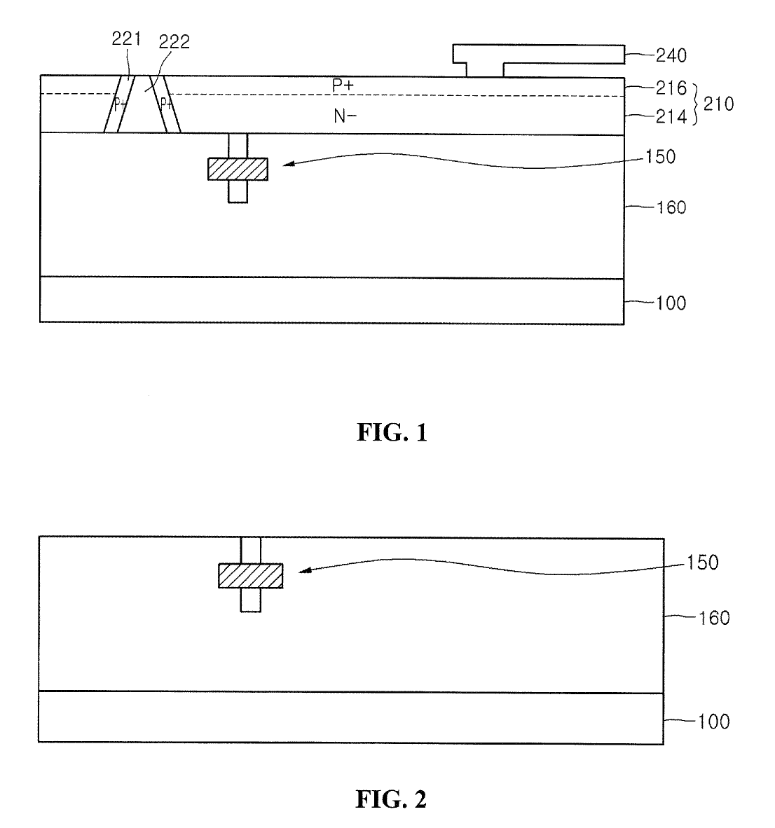

Referring to FIG. 1, an image sensor can include: a first substrate 100 including a readout circuitry (not shown) and an interconnection 150; an image sensing device 210 on the interconnection 150; and a light shielding layer 222 on a boundary between pixels.

The image sensing device 210 can be, but is not limited to, a photodiode. For example, the image sensing device 210 can be a photogate or a combination of a photodiode and a photogate. Meanwhile, though the embodiment describes the photodiode 210 as being formed in a crystalline semiconductor layer, the photodiode is not limited thereto, but can be formed in an amorphous semiconductor layer.

Reference numerals not explained in FIG. 1 are described in the following manufacturing method.

Hereinafter, a method for manufacturing an image sensor according to an embodiment is described with reference to FIGS. 2 to 9.

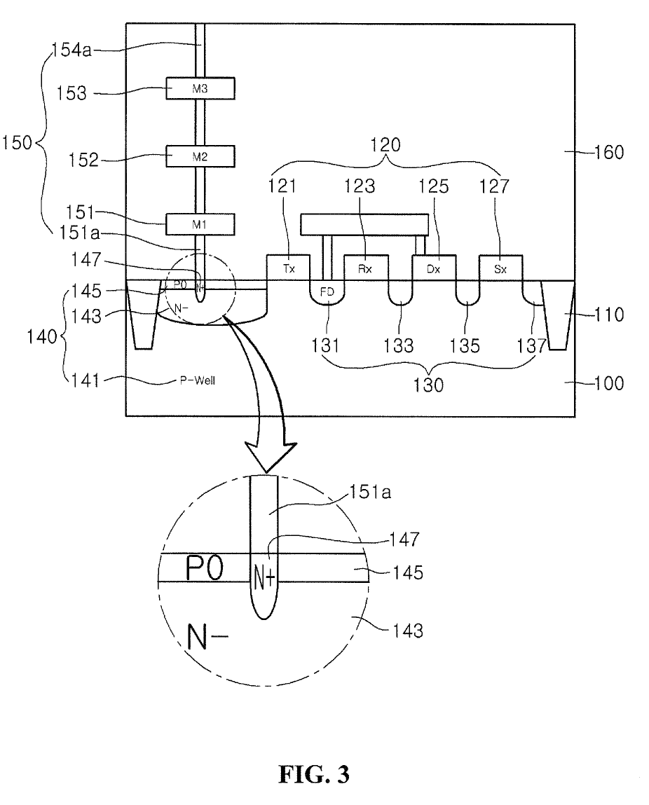

FIG. 2 is a brief cross-sectional view of an image sensor showing a first substrate 100 including interconnection 150. And FIG. 3 is a detail cross-sectional view of one embodiment of the image sensor showing a first substrate 100 including the readout circuitry 120 and the interconnection 150. Now, an image sensor according to an embodiment as shown in FIG. 3 will be described.

The first substrate 100 in which the interconnection 150 and the readout circuitry 120 are formed is prepared. For example, referring to FIG. 3, a device isolation layer 110 can be formed in the second conduction type first substrate 100, so that an active region is defined. Then, the readout circuitry 120 including a transistor can be formed in the active region. For example, the readout circuitry 120 can include a transfer transistor Tx 121, a reset transistor Rx 123, a drive transistor Dx 125, and a select transistor Sx 127. After that, a floating diffusion region FD 131 and ion implantation regions 130 including source/drain regions 133, 135, and 137 of respective transistors can be formed. Also, according to an embodiment, a noise removal circuit (not shown) can be added to improve sensitivity.

The forming of the readout circuitry 120 on the first substrate 100 can include forming an electrical junction region 140 in the first substrate 100, and forming a first conduction type connection region 147 connected with the interconnection 150 on the electrical junction region 140.

The electrical junction region 140 can be, but is not limited to, a PN junction 140. For example, the electrical junction region 140 can include a first conduction type ion implantation layer 143 formed on a second conduction type well 141 (or a second conduction type epitaxial layer), and a second conduction type ion implantation layer 145 formed on the first conduction type ion implantation layer 143. For example, the PN junction 140 can be, but is not limited to, a P0 (145)/N− (143)/P− (141) junction such as shown in FIG. 3. In certain embodiments, the first substrate 100 can be a second conduction type substrate.

According to an embodiment, a device is designed such that there is a potential difference between the source and drain at the sides of the transfer transistor Tx, so that a photo charge can be fully dumped. Accordingly, a photo charge generated from the photodiode is fully dumped to the floating diffusion region, so that the sensitivity of an output image can be improved.

That is, according to an embodiment, the electrical junction region 140 is formed in the first substrate 100 where the readout circuitry 120 is formed to allow a potential difference to be generated between the source and the drain of the transfer transistor Tx 121, so that a photo charge can be fully dumped.

Hereinafter, a dumping structure of a photo charge according to the embodiment is described in detail.

Unlike a node of a floating diffusion FD 131, which is an N+ junction, the PNP junction 140, which is an electrical junction region 140 and to which an applied voltage is not fully transferred, is pinched-off at a predetermined voltage. This voltage is called a pinning voltage, which depends on the doping concentrations of a P0 region 145 and an N− region 143.

Specifically, an electron generated from the photodiode 210 moves to the PNP junction 140, and is transferred to the node of the floating diffusion FD 131 and converted into a voltage when the transfer transistor Tx 121 is turned on.

Since a maximum voltage value of the P0/N−/P− junction 140 becomes a pinning voltage, and a maximum voltage value of the node of the floating diffusion FD 131 becomes a threshold voltage Vth of a Vdd-Rx 123, an electron generated from the photodiode 210 in the upper portion of a chip can be fully dumped to the node of the floating diffusion FD 131 without charge sharing by implementing a potential difference between the sides of the transfer transistor Tx 131.

That is, according to an embodiment, a P0/N−/P-well junction, not an N+/P-well junction, is formed in the first substrate 100 to allow a + voltage to be applied to the N− region 143 of the P0/N−/P-well junction and a ground voltage to be applied to the P0 145 and P-well 141 during a 4-Tr active pixel sensor (APS) reset operation, so that a pinch-off is generated at the P0/N−/P-well double junction at a predetermined voltage or more as in a bipolar junction transistor (BJT) structure. This is called the pinning voltage. Therefore, a potential difference is generated between the source and the drain of the transfer transistor Tx 121 to inhibit a charge sharing phenomenon during the on/off operations of the transfer transistor Tx. Therefore, unlike a case where a photodiode is simply connected with an N+ junction as in a related art, limitations such as saturation reduction and sensitivity reduction can be avoided according to the above described embodiment.

After forming the P0/N−/P− junction 140, a first conduction type connection region 147 can be formed between the photodiode and the readout circuitry to provide a swift movement path of a photo charge, so that a dark current source is minimized, and saturation reduction and sensitivity reduction can be inhibited.

For this purpose, the first conduction type connection region 147 for ohmic contact can be formed on the surface of the P0/N−/P− junction 140. The N+ region 147 can be formed to pass through the P0 region 145 and contact the N− region 143.

Meanwhile, to inhibit the first conduction type connection region 147 from becoming a leakage source, the width of the first conduction type connection region 147 can be minimized. For this purpose, in one embodiment, a plug implant can be performed after a via hole for a first metal contact 151a is etched. However, embodiments are not limited thereto. For example, an ion implantation pattern (not shown) can be formed and the first conduction type connection region 147 can then be formed using the ion implantation pattern as an ion implantation mask.

That is, a reason of locally and heavily doping only a contact forming portion with N type impurities in the above described embodiment is to facilitate ohmic contact formation while minimizing a dark signal. In case of heavily doping the entire transfer transistor source, a dark signal may be increased by a Si surface dangling bond.

An interlayer dielectric 160 can be formed on the first substrate 100, and the interconnection 150 can be formed. The interconnection 150 can include but is not limited to the first metal contact 151a, a first metal 151, a second metal 152, a third metal 153, and a fourth metal contact 154a.

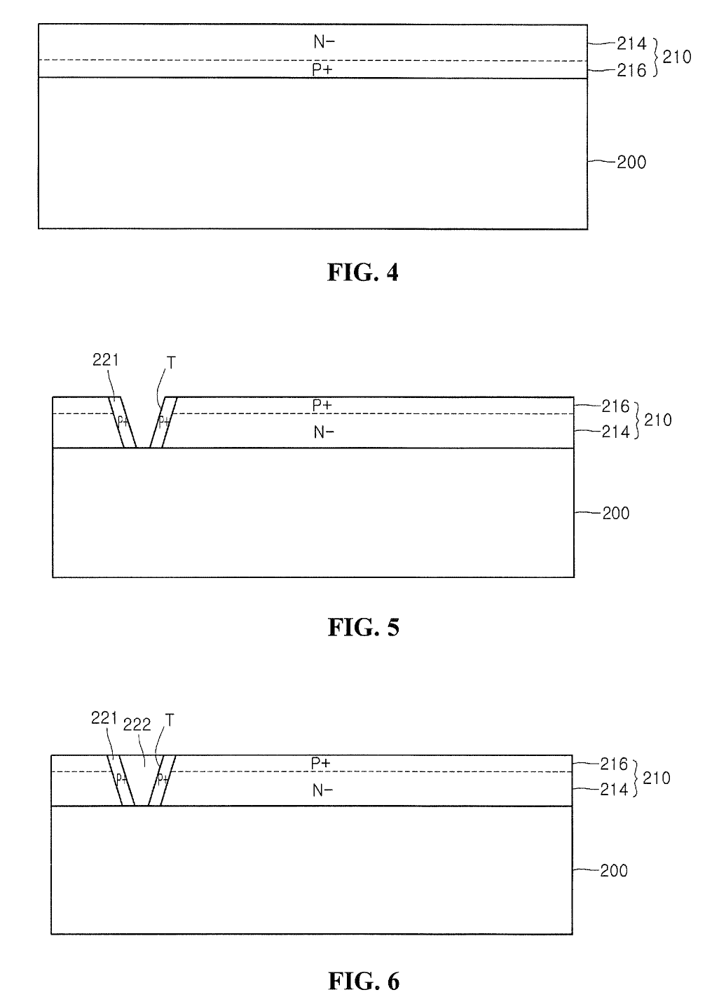

The photodiode 210 can be formed in a crystalline semiconductor layer on a second substrate 200 using an ion implantation method as illustrated in FIG. 4. For example, a second conduction type conduction layer 216 can be formed in the lower portion of the crystalline semiconductor layer. After that, a first conduction type conduction layer 214 can be formed on the second conduction type conduction layer 216.

Next, referring to FIG. 5, a trench T can be formed in the photodiode 210. The trench T can be positioned at boundaries between pixels for inhibiting cross-talk.

Next, a second conduction type ion implantation layer 221 can be formed on the surface of the trench T. For example, a second conduction type ion implantation layer 221 (P+) can be formed on the surface of the trench T by high doped P type ion implantation.

According to an embodiment, crosstalk of electrons or holes can be inhibited by forming the second conduction type ion implantation layer 221 between the photodiode 210 and the light shielding layer 222, while an electrical isolation can be further achieved by the second conduction type ion implantation layer 221.

Next, a light shielding layer 222 can be formed on the second conduction type ion implantation layer 221 by forming a metal shielding layer on the second conduction type ion implantation layer 221 in the trench. For example, the light shielding layer 222 can be formed by forming an opaque metal shielding layer on the P+ layer 221 on the trench T. Then, the light shielding layer 222 can be planarized by CMP or etch back.

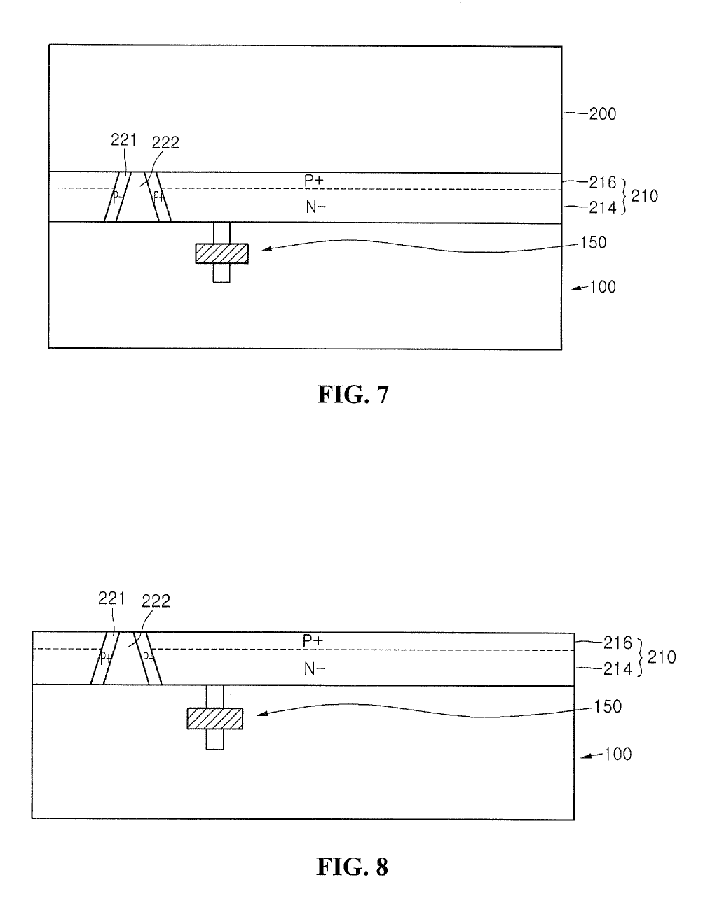

Next, referring to FIG. 7 the first substrate 100 and the second substrate 200 are bonded such that the photodiode 210 corresponds with the interconnection 150. At this point, before the first substrate 100 and the second substrate 200 are bonded to each other, the bonding can be performed by increasing the surface energy of a surface to be bonded through activation by plasma. In certain embodiments, the bonding can be performed with a dielectric or a metal layer disposed on a bonding interface in order to improve bonding force.

Also, an alignment needs not to contact between the light shielding layer 222 and the interconnection 150.

Next, a portion of the second substrate 200 can be removed using a blade or backgrinding so that the photodiode 210 can be exposed as illustrated in FIG. 8.

Meanwhile, in another embodiment, the light shielding layer 222 and the second conduction type ion implantation layer 221 can be formed after bonding of the first substrate 100 and the second substrate 200.

After removing the portion of the second substrate 200, an etching separating the photodiode for each unit pixel can be performed. Then the etched portion can be filled with an interpixel dielectric (not shown).

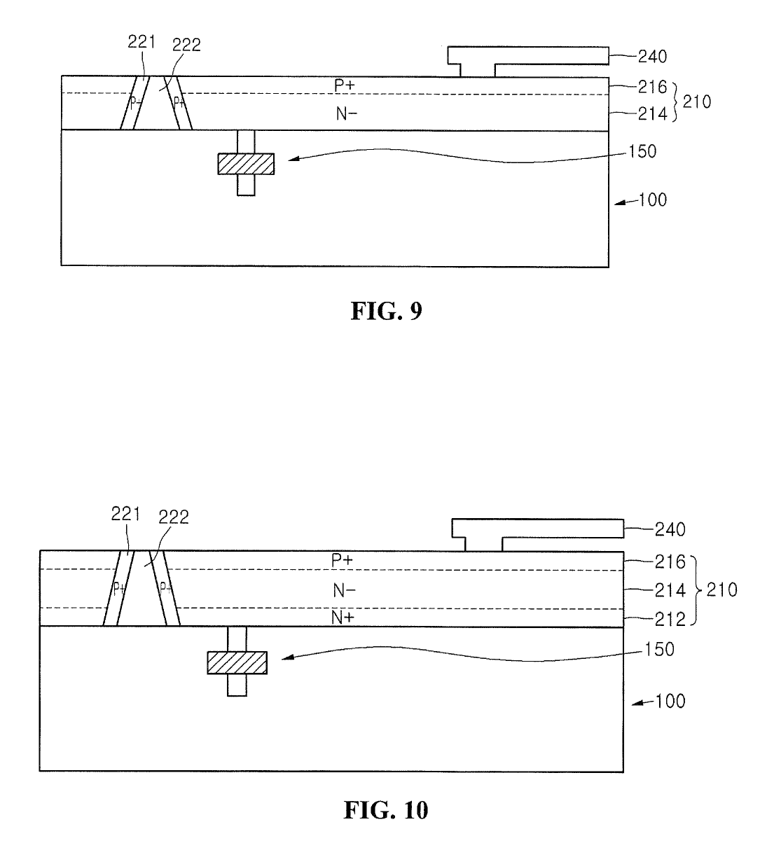

Next, referring to FIG. 9, processes for forming an upper electrode 240 and a color filter (not shown) can be performed.

FIG. 10 is a cross-sectional view of an image sensor according to another embodiment.

The embodiment can adopt the technical characteristics of the previous embodiment.

Meanwhile, according to this embodiment, a high concentration first conduction type conduction layer 212 can be formed on the first conduction type conduction layer 214 before forming the trench. For example, a high concentration N+ type conduction layer 212 can be further formed on the first conduction type conduction layer 214 by performing blanket-ion implantation on the entire surface of the second substrate 200 without a mask, so that it can contribute to ohmic contact.

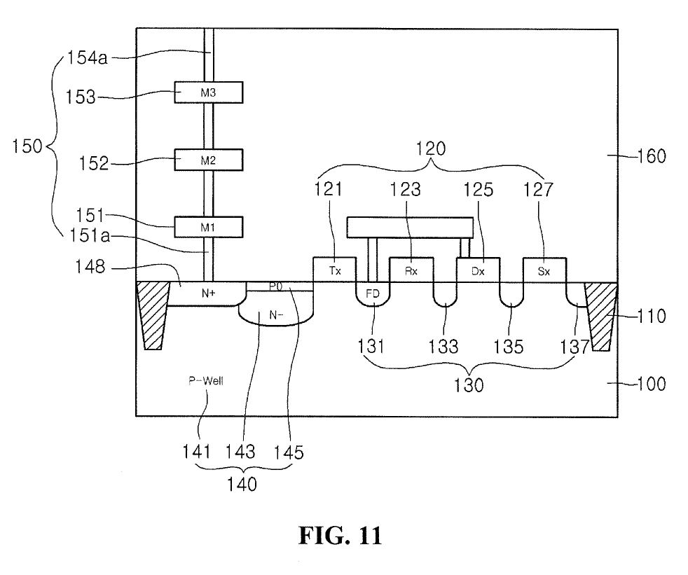

FIG. 11 is a cross-sectional view of an image sensor according to yet another embodiment, and illustrates a first substrate including an interconnection 150 in detail.

The image sensor according to an embodiment can incorporate the first substrate 100 including readout circuitry 120 and the interconnection 150 as shown in FIG. 11. These structures can be used in place of those described with respect to FIG. 3.

The present embodiment can adopt the technical characteristics of the previous embodiments.

Meanwhile, unlike the embodiment described with respect to FIG. 3, a first conduction type connection region 148 is formed at a side of the electrical junction region 140.

According to an embodiment, an N+ connection region 148 for ohmic contact can be formed adjacent the P0/N−/P− junction 140. At this point, a process of forming the N+ connection region 148 and an M1C contact 151a may provide a leakage source because the device operates with a reverse bias applied to the P0/N−/P− junction 140 and so an electric field EF can be generated on the Si surface. This occurs because a crystal defect generated during the contact forming process inside the electric field serves as a leakage source.

Also, in the case where the N+ connection region 148 is formed on the surface of the P0/N−/P− junction 140, an electric field due to the N+/P0 junction 148/145 is added. This electric field also serves as a leakage source.

Therefore, a layout in which a first contact plug 151a is formed in an active region not doped with a P0 layer but including an N+ connection region 148. Through the N+ connection region 148, the first contact plug 151a is connected with the N-junction 143.

According to an embodiment, the electric field is not generated on the Si surface. In addition, the dark current of a 3D integrated CIS can be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a first substrate including a readout circuitry and an interconnection;
an image sensing device on the interconnection; and
a light shielding layer in portions of the image sensing device on a boundary between pixels.

2. The image sensor according to claim 1, further comprising a second conduction type ion implantation layer at sides of the light shielding layer.

3. The image sensor according to claim 1, wherein the light shielding layer comprises an opaque metal shielding layer.

4. The image sensor according to claim 1, further comprising an electrical junction region electrically connecting the interconnection with the readout circuitry in the first substrate.

5. The image sensor according to claim 4, wherein the electrical junction region comprises:
a first conduction type ion implantation region in the first substrate; and
a second conduction type ion implantation region on the first conduction type ion implantation region.

6. The image sensor according to claim 4, wherein the electrical junction region provides a potential difference between a source having the electrical junction region and a drain at sides of a transistor of the readout circuitry.

7. The image sensor according to claim 4, wherein the electrical junction region comprises a PN junction.

8. The image sensor according to claim 4, further comprising a first conduction type connection region between the electrical junction region and the interconnection.

9. The image sensor according to claim 8, wherein the first conduction type connection region comprises a first conduction type connection region electrically connected with the interconnection on the electrical junction region.

10. The image sensor according to claim 8, wherein the first conduction type connection region comprises a first conduction type connection region electrically connected with the interconnection at a side of the electrical junction region.

11. A method for manufacturing an image sensor, the method comprising:
forming a readout circuitry and an interconnection in a first substrate;
forming an image sensing device in a second substrate;
forming a trench in the image sensing device;
forming a second conduction type ion implantation layer on the surface of the trench;
forming a light shielding layer in the trench on the second conduction type ion implantation layer;
bonding the first substrate and the second substrate, wherein the interconnection corresponds with the image sensing device; and
selectively removing the second substrate such that the image sensing device remains on the first substrate.

12. The method according to claim 11, wherein the light shielding layer comprises an opaque metal shielding layer.

13. The method according to claim 11, wherein the light shielding layer is formed on a boundary between pixels, and wherein the second conduction type ion implantation layer is formed at sides of the light shielding layer.

14. The method according to claim 11, further comprising forming an electrical junction region electrically connected with the readout circuitry in the first substrate.

15. The method according to claim 1, wherein forming the electrical junction region comprises:
forming a first conduction type ion implantation region in the first substrate; and
forming a second conduction type ion implantation region on the first conduction type ion implantation region.

16. The method according to claim 14, wherein the electrical junction region is formed to provide a potential difference between a source having the electrical junction region and a drain at sides of a transistor of the readout circuitry.

17. The method according to claim 14, wherein the electrical junction region comprises a PN junction.

18. The method according to claim 14, further comprising forming a first conduction type connection region between the electrical junction region and the interconnection.

19. The method according to claim 18, wherein the first conduction type connection region comprises a first conduction type connection region electrically connected with the interconnection on the electrical junction region.

20. The method according to claim 18, wherein the first conduction type connection region comprises a first conduction type connection region electrically connected with the interconnection at a side of the electrical junction region.
